(19) United States
(12) Patent Application Publication
(10) Pub. No.: US 2026/0121379 A1
(43) Pub. Date: Apr. 30, 2026

(54) METHOD FOR PREPARING A PHOTONIC CRYSTAL LASER AND A PHOTONIC CRYSTAL LASER

(71) Applicant: WUHAN UNIVERSITY, Hubei (CN)

(72) Inventors: Yongquan ZENG, Hubei (CN); Shouqi ZHANG, Hubei (CN)

(73) Assignee: WUHAN UNIVERSITY, Hubei (CN)

(21) Appl. No.: 19/008,579

(22) Filed: Jan. 2, 2025

(30) Foreign Application Priority Data
Jul. 8, 2024 (CN) 202410906010.5

(51) Int. Cl. H01S 5/11; H01S 5/10; H01S 5/34

(52) U.S. Cl. CPC H01S 5/11; H01S 5/1042; H01S 5/34

(57) ABSTRACT

The invention provides a preparation method of a photonic crystal laser and a photonic crystal laser itself. The method includes: creating a two-dimensional periodic array of air holes on a semiconductor wafer to form a photonic crystal, and each primitive cell of the array contains one air hole; the photonic crystal is divided into a left domain and a right domain; shift the left domain to the left by the first preset distance; shift the right domain to the left by a second preset distance, or rotate the right domain by a preset angle along a point on the interface between the left domain and the right domain; truncate the right domain along the interface and keep the right part of right domain. This invention enables the creation of photonic crystal lasers with advantages such as broad spectral bandwidth, multiple wavelengths, low threshold, and high power.

### CROSS-REFERENCE TO RELATED APPLICATIONS

This application claims the benefit of priority from Chinese Patent Application No. 202410906010.5, filed on Jul. 8, 2024. The content of the aforementioned-application, including any intervening amendments thereto, is incorporated herein by reference in its entirety.

### The Technical Field

The present invention relates to the field of laser technology, specifically to a method for preparing a photonic crystal laser and a photonic crystal laser.

### The Background Technology

Topological photonics is a new branch of photonics research in recent years, originating from condensed matter and widely applied in various fields such as directional waveguides, optical delay lines, filters, power splitters, resonators, and lasers. The concept of synthetic dimension has been introduced into topological photonics in recent years, which can support the study of high-dimensional topological phenomena in low dimensional practical structures, further increasing the degree of control freedom.

High performance, multi-wavelength optical devices are important components of on-chip nano optical chips, which can be used for applications such as high-capacity optical communication and high-speed information processing. However, traditional structures are limited by materials and complex designs, which affect the precision of nanomachining and pose certain technical difficulties to achieve the above requirements

### The Invention Content

The purpose of the present invention is to provide a method for preparing a photonic crystal laser and a photonic crystal laser, which can solve the problems of traditional structures in the prior art, such as material limitations and complex design, affecting the accuracy of nano processing. It can achieve a photonic crystal laser with advantages such as broadband, multi-wavelength, low threshold, and high power.

In order to achieve the above objectives, in the first aspect, the present invention provides a method for preparing a photonic crystal laser, comprising:
fabricating a plurality of air holes arranged in arrays to form a photonic crystal and the plurality of air holes being respectively located on a plurality of primary cells of the photonic crystal;
dividing the photonic crystal into a left region and a right region;
shifting the left region to the left for a first preset distance;
shifting the right region to the left by a second preset distance, or rotating the right region with a preset angle along a point on an interface between the left region and the right region wherein a portion of the right region located at a right side of the interface are preserved.

According to the preparation method of the photonic crystal laser provided by the present invention, the range of the first preset distance is:

$$0 \leq ds \leq 0.35 a ,$$

wherein ds is the first preset distance and a is a lattice constant of the photonic crystal.

According to the preparation method of the photonic crystal laser provided by the present invention, an expression for the second preset distance is:

$${Δ}_{i} = \frac{( i - 1 ) a}{n} ,$$

wherein Δᵢ is a second preset distance of a translation of an ith row of the air holes, a is a lattice constant of the photonic crystal, and n is a total number of rows of the air holes.

According to the preparation method of the photonic crystal laser provided by the present invention, an expression for the second preset distance is:

$${Δ}_{i} = a [ \frac{i - 1}{n} + \frac{sin ( \frac{2 π ( i - 1 )}{n} )}{3 π} ] ,$$

wherein Δᵢ is a second preset distance of a translation of an ith row of the air holes, a is a lattice constant of the photonic crystal, and n is a total number of rows of the air holes.

According to the method for preparing the photonic crystal laser provided by the present invention, in the step of rotating the right region with the preset angle along the point on the interface between the left region and the right region, comprising:
rotating the right region clockwise along the point at a top of the interface to the preset angle ranging from 0° to 30°.

According to the preparation method of the photonic crystal laser provided by the present invention, wherein the photonic crystal is formed on the semiconductor wafers with different gain material design including quantum wells, quantum dots, or superlattices.

According to the preparation method of the photonic crystal laser provided by the present invention, a lattice arrangement of the photonic crystal includes square lattice, triangular lattice, tetragonal lattice, and honeycomb lattice.

According to the preparation method of the photonic crystal laser provided by the present invention, a shape of the air holes can be circular, triangular, rectangular, or hexagonal.

According to the preparation method of the photonic crystal laser provided by the present invention, the shape of the air holes is circular and the relationship between the diameter of the air hole and the lattice constant is:

$$0.1 \leq \frac{d}{a} \leq 0.95 ,$$

wherein d is the diameter of the air holes and a is the lattice constant of the photonic crystal.

In the second aspect, the present invention provides a photonic crystal laser using the preparation method of the photonic crystal laser of the first aspect.

The present invention provides a method for preparing a photonic crystal laser and a photonic crystal laser, the method comprising: fabricating a plurality of air holes arranged in arrays to form a photonic crystal and the plurality of air holes being respectively located on a plurality of primary cells of the photonic crystal; dividing the photonic crystal into a left region and a right region; shifting the left region to the left for a first preset distance; shifting the right region to the left by a second preset distance, or rotating the right region with a preset angle along a point on an interface between the left region and the right region wherein a portion of the right region located at a right side of the interface are preserved. The present invention can realize a photonic crystal laser with advantages such as broadband, multi wavelength, low threshold, and high power.

### THE DESCRIPTION OF THE ATTACHED IMAGE

In order to illustrate the technical solutions of the present invention or the prior art more clearly, a brief introduction will be given to the drawings required for the embodiments or the prior art description. It is obvious that the drawings described below are some embodiments of the present invention. For those skilled in the art, other drawings can be obtained based on these drawings without creative labor.

In the attached figure:

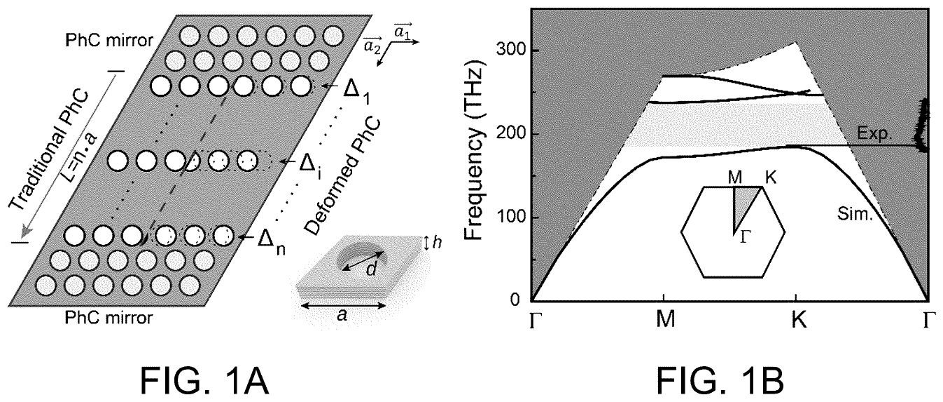

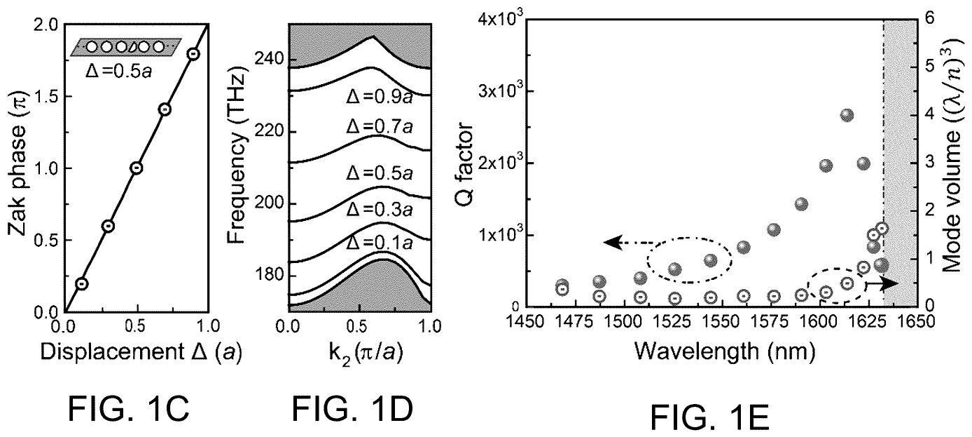

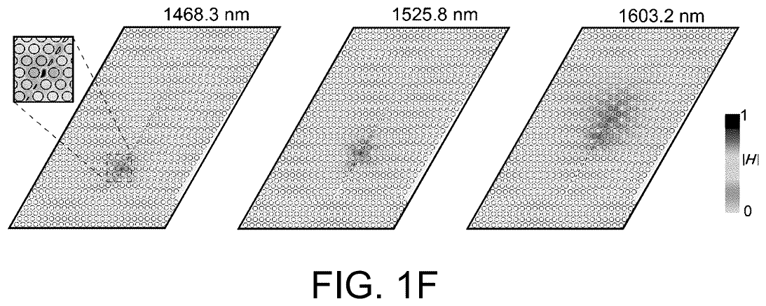

FIG. 1A shows a schematic diagram of the structure of a photonic crystal laser constructed using a translation method according to the present invention.

FIG. 1B shows the distribution of the first and second energy bands of the photonic crystal unit cell in FIG. 1A.

FIG. 1C shows the numerical relationship of topological invariants corresponding to different linear translation displacement factor in FIG. 1A.

FIG. 1D shows the band distribution of the super cell of photonic crystal under different displacement factors in FIG. 1A.

FIG. 1E is a schematic diagram of the quality factor and mode volume of the eigen-topological-synthetic-modes in FIG. 1A when the cavity length is 25a.

FIG. 1F shows the distribution of the normalized magnetic field of the eigen-modes in FIG. 1A at different wavelengths.

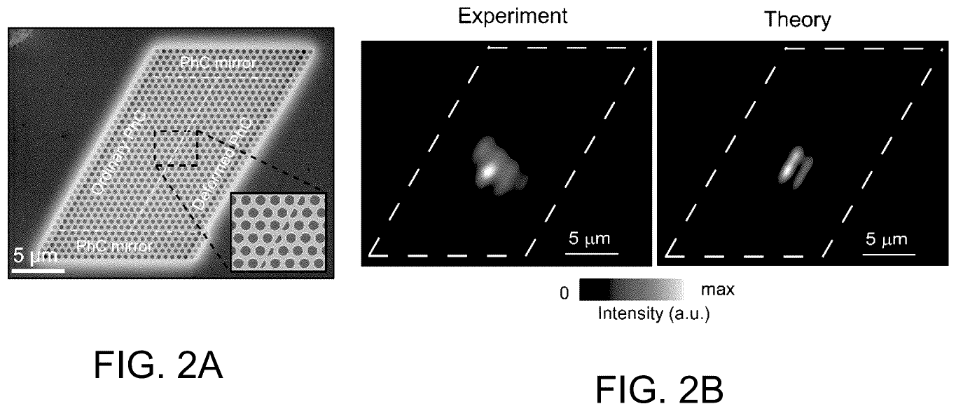

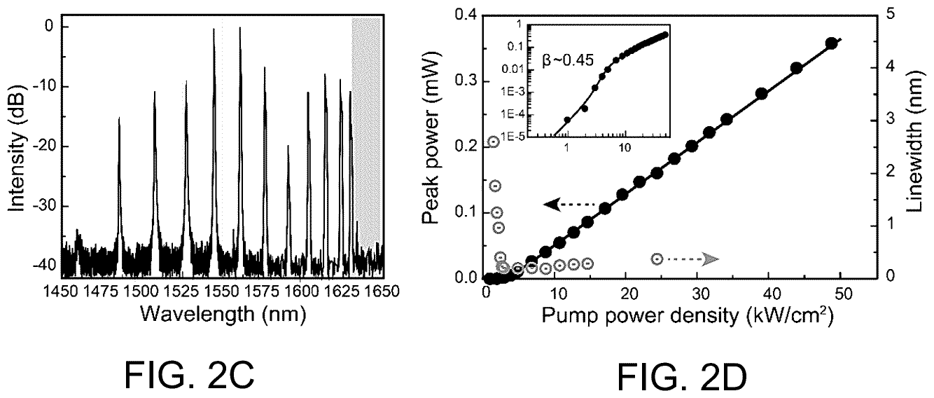

FIG. 2A shows the electron microscopy image of a photonic crystal laser with a cavity length of 25a in the experiment.

FIG. 2B shows the experimental and fitted laser radiation profiles of the laser.

FIG. 2C shows the radiation spectrum of a photonic crystal laser in the wavelength domain.

FIG. 2D shows the input-output curve of the laser and the variation of the linewidth of the topologically synthetic modes with pump power.

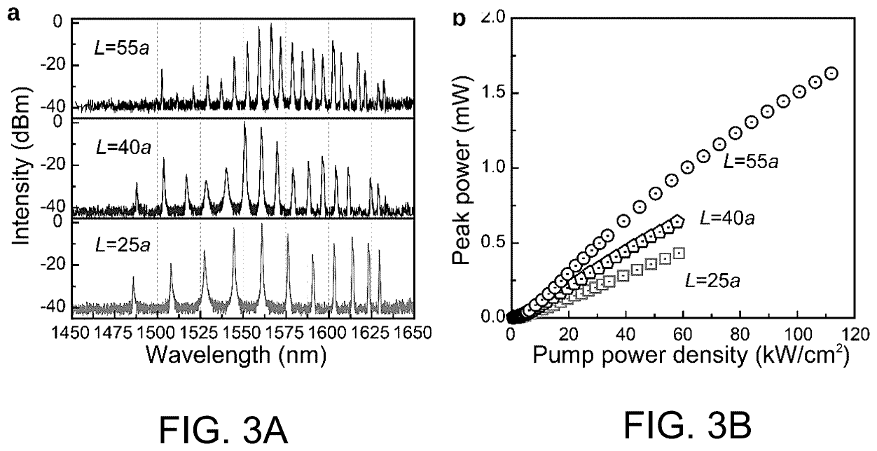

FIG. 3A shows the laser radiation spectrum of a photonic crystal laser with different cavity lengths.

FIG. 3B shows the input-output curves of photonic crystal lasers with different cavity lengths.

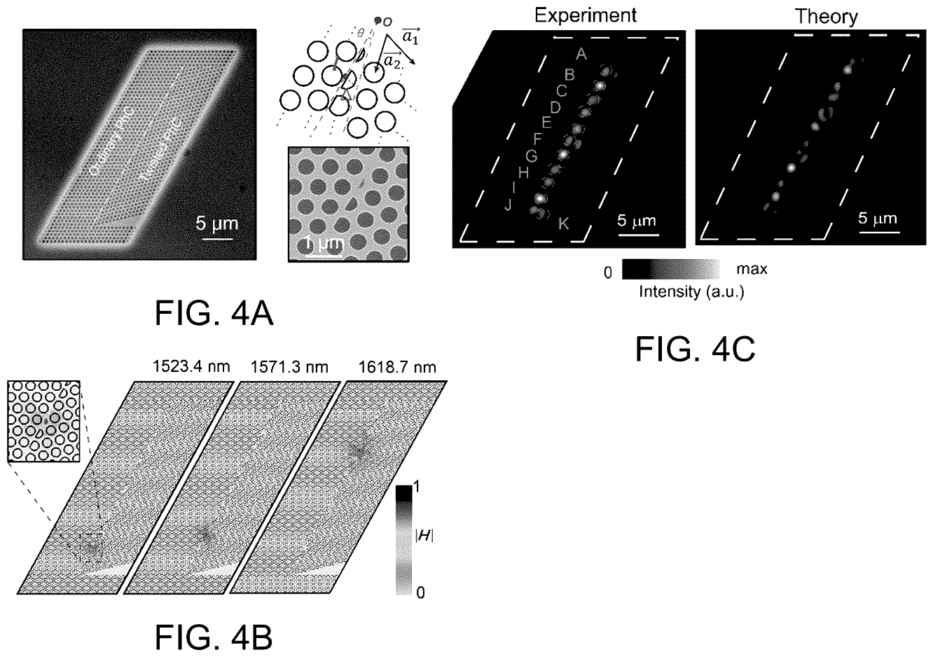

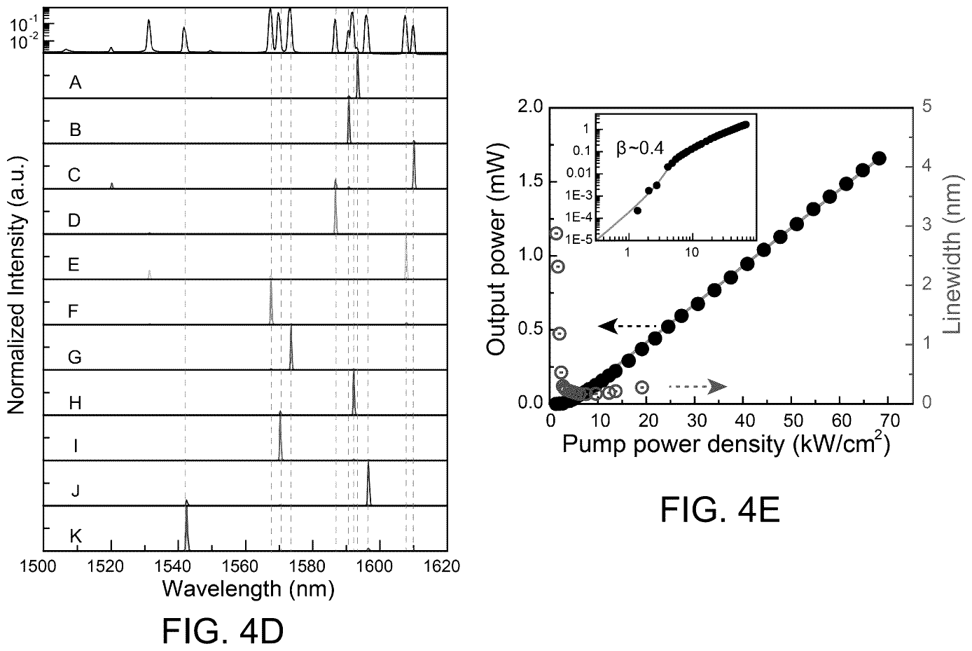

FIG. 4A shows the electron microscope image of the photonic crystal laser constructed by the rotation method in the present invention.

FIG. 4B shows the mode distribution with different wavelengths corresponding to that in FIG. 4A.

FIG. 4C shows the laser radiation pattern diagram of the experiment and simulation corresponding to that in FIG. 4A.

FIG. 4D shows the laser emission spectrum of FIG. 4A and the corresponding spectra at different positions.

FIG. 4E shows the input-output curves and corresponding fitting curves obtained from the laser device in FIG. 4A, as well as the variation of linewidth with increasing pump power.

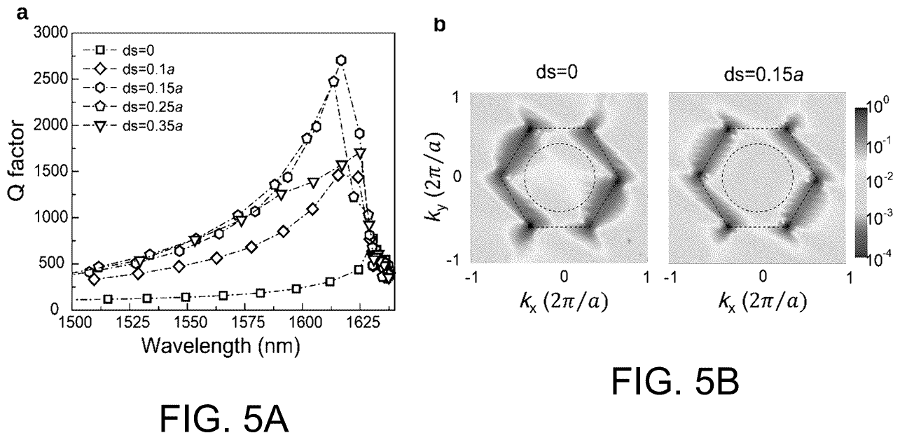

FIG. 5A shows the relationship between the quality factor of the topologically synthetic mode of the present invention and the first preset distance ds of the left photonic crystal translation.

FIG. 5B shows the Fourier transform of momentum space when ds=0 and ds=0.15a.

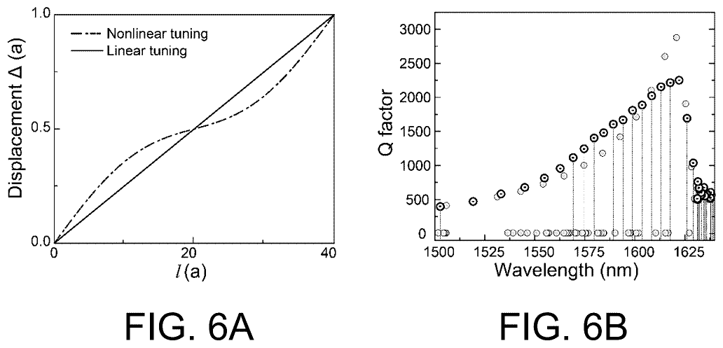

FIG. 6A shows the relationship between spatial position along the interface and displacement for the second preset distance of the photonic crystal movement on the right, which satisfies a linear modulation function and a nonlinear modulation function, respectively.

FIG. 6B shows the distribution of wavelengths and quality factors under two modulation functions.

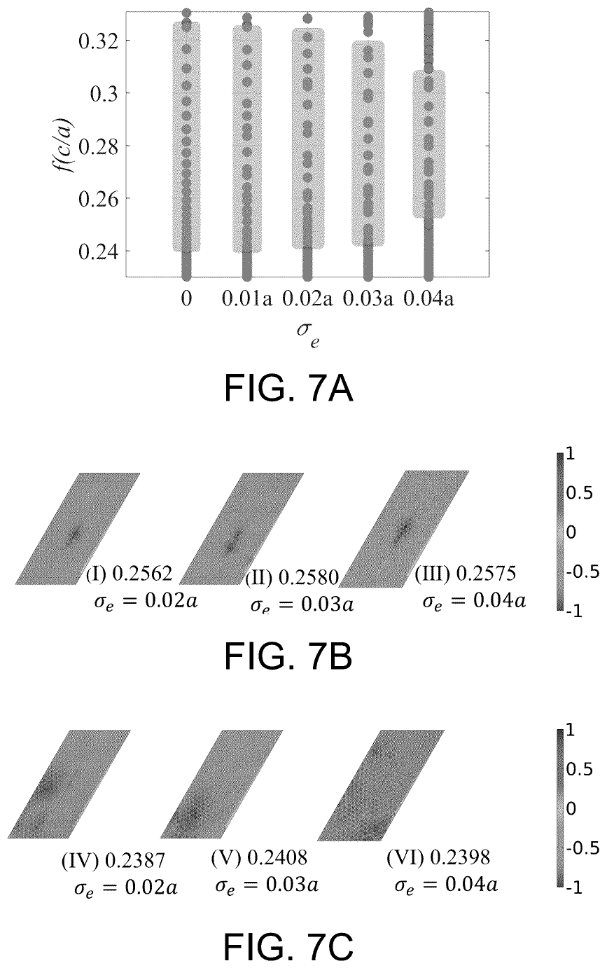

FIG. 7A shows the distribution of the normalized frequency f under different disturbance intensities σₑ.

FIG. 7B shows the distribution of the mode field of typical topologically synthetic modes under different defect strengths.

FIG. 7C shows the distribution of the mode field of topologically synthetic mode introduced by defect disturbances at different defect intensities.

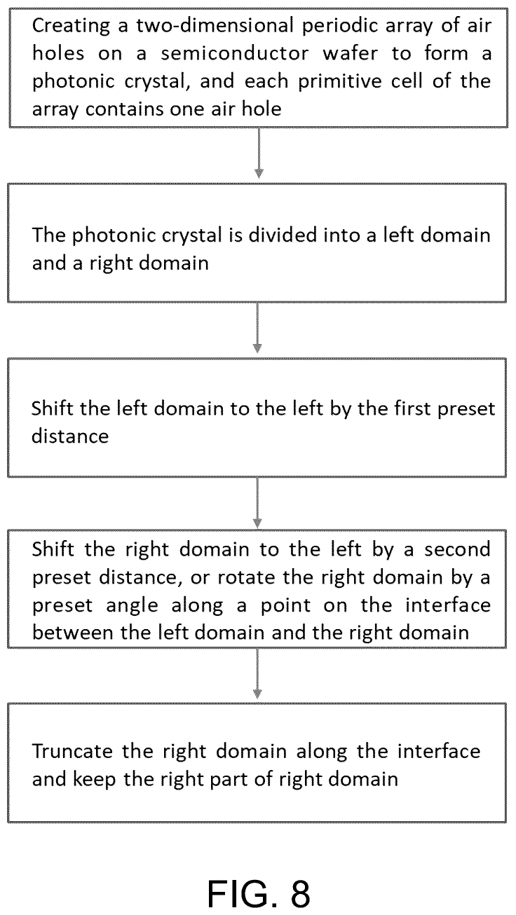

FIG. 8 is a flowchart of the preparation method of the photonic crystal laser of the present invention.

### THE SPECIFIC IMPLEMENTATION METHODS

In order to clarify the purpose, technical solution, and advantages of the present invention, the technical solution of the present invention will be described clearly and completely in conjunction with the accompanying drawings. Obviously, the described embodiments are a part of the embodiments of the present invention, not all of them. Based on the embodiments of the present invention, any other embodiments obtained by ordinary skilled persons in the art without creative labor are within the scope of protection of the present invention.

Below, some embodiments of the present invention will be described in detail with reference to the accompanying drawings. In non-conflicting situations, the following embodiments and their features can be combined with each other.

Please refer to FIG. 8. The present invention provides a method for preparing a photonic crystal laser, comprising:

Step 1: Fabricate a plurality of air holes arranged in arrays to form a photonic crystal and the plurality of air holes being respectively located on a plurality of primary cells of the photonic crystal.

Specifically, photonic crystals is formed on the semiconductor wafers with different gain material design, including quantum wells, quantum dots, superlattices, and other laser gain materials. Photonic crystals can also use laser gain materials, such as quantum wells, quantum dots, superlattices, and other laser gain materials, heterogeneously-integrated on the low-index and low-loss substrate, such as SiO2, SiC, and other materials. The lattice arrangement types of photonic crystals include square lattice, triangular lattice, tetragonal lattice, honeycomb lattice, etc. The method of opening air holes in step 1 can be etching. The shape of the air hole can be circular, triangular, rectangular, hexagonal, etc. The etching pattern can be a hole shaped etching pattern or a pillar shaped etching pattern, etc. The polarization mode of photonic crystals can be either the Transverse-Electric (TE) mode or the Transverse-Magnetic (TM) mode. Photonic crystals are not limited to two-dimensional structures in terms of spatial arrangement, and three-dimensional or one-dimensional structures can also be used to construct resonant cavities.

Step 2: Divide the photonic crystal into left and right regions.

Step 3: Shift the left region to the left by the first preset distance.

Step 4: As shown in FIG. 1A, shift the right region to the left by a second preset distance, or, as shown in FIG. 4A, rotate the right region by a preset angle along a point on the interface between the left and right regions, wherein retaining a portion of the right region located on the right side of the interface are preserved.

Therefore, the part of the photonic crystal located on the left side of the interface is an undeformed photonic crystal, and the part located on the right side of the interface is a deformed photonic crystal, thus constructing a resonant cavity. The supercell of the photonic crystal consists of two parts: one is an undeformed photonic crystal, and the other is a deformed photonic crystal. The second preset distance Δᵢ can reflect the degree of deformation of the photonic crystal. The second preset distance Δᵢ determines the cavity resonant frequencies. By controlling the different sizes of Δᵢ, the frequency distribution of the topologically synthesized band can be distributed throughout the entire bandgap.

It should be noted that the photonic crystal is a solid structure composed of gain materials, and there is a periodic array of air hole structures arranged on the solid structure. The structure of the photonic crystal supports a series of topologically synthetic modes spanning across the large bandgap, which have characteristics such as small modes and appropriate Q values (Quality Factor). Small modes ensure that these topologically synthetic modes are separated in space, and topologically synthetic mode can be simultaneously stimulated by gain in the active materials (such as semiconductor materials). Small modes also affect the Purcell factor (the ratio of the field intensity in the cavity to the field intensity in the uniform medium), increasing the Purcell factor and ensuring the smooth excitation of the target topologically synthetic mode. At the same time, it also affects the threshold and reduces it to a certain extent. These characteristics can ensure the smooth implementation of the multi-wavelength, low threshold, and broadband features of the laser, thus forming a topological rainbow resonator. And an appropriate quality factor ensures that the threshold is not too high, while also ensuring the efficiency of the laser radiating into free space, ensuring that high-power output can be achieved.

In some embodiments, in step 3, the range of the first preset distance is:

$$0 \leq d s \leq 0.35 a .$$

In the formula, ds is the first preset distance, and a is the lattice constant of the photonic crystal. The optimal value for ds is 0.15a, at which point the Q value is at its maximum.

In step 4, the expression for the second preset distance is:

$${Δ}_{i} = \frac{( i - 1 ) a}{n} .$$

In the formula, Δᵢ is the second preset distance for the translation of the ith row of air holes and their corresponding primitive cells, a is the lattice constant of the photonic crystal, and n is the total number of rows of the air holes.

In other embodiments, the expression for the second preset distance is:

$${Δ}_{i} = a [ \frac{i - 1}{n} + \frac{sin ( \frac{2 π ( i - 1 )}{n} )}{3 π} ] .$$

In the formula, Δᵢ is the second preset distance for the translation of the ith row of air holes and their corresponding primitive cells, a is the lattice constant of the photonic crystal, and n is the total number of rows of the air holes.

When the shape of the air hole is a circular hole, the relationship between the diameter of the air hole and the lattice constant is:

$$0.1 \leq \frac{d}{a} \leq 0.95 .$$

In the formula, d is the diameter of the air hole, and a is the lattice constant of the photonic crystal.

By controlling the lattice constant a of the photonic crystal and the diameter d of the air hole, the size of the bandgap between the first and second energy bands of this type of photonic crystal, as well as the frequency range in which the bandgap is located, can be controlled. In addition, the air hole in the ith row and the original cell it is located in move in the opposite direction of the original cell base vector \vec{a₁} by a distance of Δᵢ, where Δᵢ and the lattice constant a satisfy:

$$0 \leq \frac{{Δ}_{i}}{a} \leq 1 .$$

By changing Δᵢ, the topological invariant Zak phase calculated will change accordingly, enabling continuous changes in topological properties of the photonic crystal.

Specifically, in step 4, rotate the right region along the interface between the left and right regions by a preset angle, which includes:

Rotate the right region clockwise along a point at the top of the interface by a preset angle, which ranges from 0° to 30°, preferably with a rotation angle of 13°.

The following further describes the arrangement of air holes and their original cells. The air holes on the left side of the interface are arranged in a triangular lattice, filling the space along the two vector directions of \vec{a₁} and \vec{a₂}. On the right side of the interface, it is necessary to translate the air holes arranged in the triangular lattice and the original cells they are located in, with varying distances along the interface from top to bottom. Taking the cavity length L=25a as an example, that is, the total number of rows of hollow air holes arranged in the resonant cavity is 25, the corresponding movement distance of the ith row of air holes and the original cell they are located in is:

$${Δ}_{i} = \frac{( i - 1 ) a}{25} .$$

A series of topologically synthetic modes are supported in the lattice bandgap. By moving the photonic crystal on the right side of the resonant cavity in the opposite direction \vec{a₁}, a deformed photonic crystal is formed; By moving the photonic crystal on the left side of the resonant cavity by a suitable distance 0.15a, the overall quality factor of the topologically synthetic mode is improved, which ensures the reduction of the laser threshold and enables smooth excitation of the topologically synthetic mode. On the other hand, an appropriate quality factor also ensures high coupling efficiency and achieves high-power output.

The structure of the photonic crystal also has good robustness. The results show that when subjected to uniformly large disturbances, as long as the bandgap is not closed, there are still a series of topologically synthetic modes localized at the interface, ensuring that the photonic crystal laser still operates in the target mode rather than the defect type mode.

Based on the same invention idea, the invention also provides a photonic crystal laser, which is prepared by the preparation method of the photonic crystal laser in the above embodiment.

The following is a specific embodiment of the present invention in which, in order to demonstrate the unique properties of the topological rainbow photonic crystal laser provided by the present invention, the inventor experimentally realizes a two-dimensional triangular lattice photonic crystal structure with periodic arrangement of air holes (refractive index of air is 1) on a substrate of a quantum well material (refractive index of quantum well material is 3.27). Lattice constant a=644 nm, air hole is a circular hole, air hole diameter d=468 nm, photonic crystal slab thickness h=120 nm.

FIG. 1A is a schematic diagram of the structure of a photonic crystal laser with a synthetic dimension mechanism constructed using a translation method. Its topological rainbow resonant cavity is mainly composed of two parts. The left side of the black diagonal line represents an undeformed photonic crystal, and the right side represents a deformed photonic crystal. The deformed photonic crystal is achieved through translation and cutting. The range of deformation of deformable photonic crystals varies from 0 to a. FIG. 1B shows the distribution of the first and second energy bands of the photonic crystal cell, with a bandgap range between 184.86 THz and 237.68 THz, as indicated by the shallow shaded area. FIG. 1D shows the energy band distribution of photonic crystal supercells at different displacement amounts Δ (i.e. Δᵢ=0.1a, 0.3a, 0.5a, 0.7a, 0.9a). By changing Δᵢ, the Zak Phase of the photonic crystal also changes, resulting in a series of topologically synthetic modes in the bandgap. From FIG. 1C, it can be seen that taking the cavity length of 25a as an example, the energy band of the topologically synthetic mode fills the entire bandgap. FIG. 1C shows the values of the topological invariant Zak phase corresponding to different linear translation displacements A. The circles mark the Zak phase on the black line at different displacement amounts Δᵢ=0.1a, 0.3a, 0.5a, 0.7a, 0.9a, which have one-to-one correspondence with the energy bands in FIG. 1D. FIG. 1E shows the quality factor Q and mode volume of the topologically synthetic mode when the cavity length of the resonant cavity is 25a. FIG. 1F shows the distribution of the mode field |H| of topologically synthetic modes at three wavelengths. It can be seen that the mode field is mainly distributed at the interface, with good spatial localization and isolation from each other. By moving the photonic crystal on the left side of the interface in the opposite direction \vec{a₁} of 0.15a, the appropriate quality factor and small mode volume can be obtained. These characteristics ensure the smooth excitation of multi-wavelength topologically synthetic modes.

FIG. 2A shows the electron microscopy image of a photonic crystal laser with a cavity length of 25a in the experiment, including a panoramic view and a detailed view of the cut circle at the interface. FIG. 2C shows the radiation spectrum of a photonic crystal laser in the wavelength domain. Through the above design and optimization, 11 topologically synthetic modes can be achieved for laser emission. FIG. 2D shows the input-output curve of the laser (the horizontal axis represents the pump power density of external light, and the vertical axis represents the peak power generated by the photonic crystal laser) (the black dots are the experimentally measured data, and the black lines are the theoretically fitted line based on laser dynamics calculation) and the variation of the topologically synthetic mode linewidth with pump power. From the fitted curve, it can be seen that the @ factor (a laser evaluation index, that is, the proportion of spontaneous emission entering a specific laser mode) is about 0.45, and the output power can reach the mW level. FIG. 2B shows the experimental and fitted laser radiation profiles, with the image captured by the infrared camera on the left and the simulated fitted image on the right.

To further analyze the influence of cavity length on the performance of topological rainbow photonic crystal lasers. FIG. 3A shows that when the cavity length L is 25a, 40a, and 55a, it can be seen that as the cavity length increases, the number of topologically synthetic modes excited also increases, ensuring smooth excitation of more than 10 modes. FIG. 3B shows the input-output curves of the topological rainbow photonic crystal laser with different cavity lengths mentioned above. It can be seen that as the cavity length increases, the output power of the laser is further improved. When the cavity length 55a, the maximum output power can reach 1.63 mW.

The topological rainbow photonic crystal laser can construct a synthetic dimensional resonant cavity by cutting one side of the photonic crystal by rotating it at a specific angle. FIG. 4A shows the electron microscope image of a photonic crystal laser with a synthetic dimensional mechanism created by rotating it around the O point at an angle θ of 13 degrees using a rotation method. FIG. 4B shows the distribution of the mode field maps corresponding to wavelengths of 1523.35 nm, 1571.33 nm, and 1618.65 nm (|H|, for different wavelengths, distribution the mode is in different regions of the interface. Compared with the laser constructed by translational cutting, the mode volume of the rotating structure is smaller, and they are also offset from each other in space, ensuring the smooth excitation of multiple topologically synthetic modes. FIG. 4C shows the laser radiation mode map of the rotating structure laser, with images taken in the experiment on the left and simulated fitting images on the right. FIG. 4D shows the laser excitation spectrum of a rotating laser, indicating the implementation of multiple topologically synthetic modes of excitation. The wavelength distribution obtained from measurements taken at different spatial locations is also different, proving that these modes are highly separated in both spatial and wavelength domains. This is also an important factor in achieving multi-wavelength laser emission. FIG. 4E shows the input-output curves (black solid circles) and corresponding fitting curves (black lines) obtained from the experiment of a laser constructed by twisted method. The variation of linewidth with increasing pump power (represented by gray circles) is also presented. This type of laser can also achieve mW level power output, with a maximum of 1.64 mW. After fitting the beta factor, it can reach 0.4, and FIG. 4E also shows the trend of linewidth with pump power. It can be seen that after crossing the threshold, the linewidth rapidly narrows, with the narrowest reaching 0.165 nm. The Q value measured in the experiment can reach 9500.

FIG. 5A is the relationship between the quality factor of the topologically synthetic mode and the first preset distance ds of the left photonic crystal translation. When ds=0.15a, the overall quality factor is maximized. Therefore, in constructing lasers, the selected parameter for ds is 0.15a. FIG. 5B shows the momentum space of the mode with the highest quality factor when ds=0 and ds=0.15a. By adjusting the ds parameter, the proportion of components in the light cone is effectively reduced (the black circle represents the light cone), and the quality factor is increased from 440 to 2650.

By modulating the second preset distance of the photonic crystal on the right side as a function of the resonant cavity position, the resonant wavelength of the topologically synthetic mode is changed. FIG. 6A shows the linear modulation and nonlinear modulation of Δᵢ. The linear modulation function is

$${Δ}_{i} = \frac{( i - 1 ) a}{n} ,$$

and the nonlinear modulation function is

$${Δ}_{i} = a [ \frac{i - 1}{n} + \frac{sin ( \frac{2 π ( i - 1 )}{n} )}{3 π} ] .$$

FIG. 6B shows the wavelength distribution of resonant modes under two modulation functions. It can be seen that the wavelength of the resonant mode has changed, and an equidistant distribution can be achieved in some ranges by nonlinear modulation of Δᵢ.

FIGS. 7A to 7C show the robustness test results of the synthesized dimensional semiconductor laser. FIG. 7A shows the distribution of the intrinsic frequency f under different disturbance intensities σₑ, where c is the speed of light. It can be seen that as the disturbance intensity gradually increases, the effective bandgap of the laser structure gradually decreases, but the topologically synthetic modes existing within the effective bandgap still exist stably. The mode field is localized at the interface and does not diffuse towards the body, as shown in FIG. 7B. FIG. 7C shows the pattern where defect types are introduced within the original bandgap due to strong structural disturbances.

People skilled in this field will easily come up with other embodiments of the present invention after considering the specification and practicing the embodiments disclosed herein. The present invention is intended to encompass any variations, uses, or adaptive changes of the present invention, which follow the general principles of the present invention and include common knowledge or customary technical means in the art not disclosed herein. It should be understood that the present invention is not limited to the precise structure described above and shown in the accompanying drawings, and various modifications and changes can be made without departing from its scope. The scope of the present invention is limited only by the appended claims.

What is claimed is:

1. A preparation method for a photonic crystal laser, comprising:
fabricating a plurality of air holes arranged in arrays to form a photonic crystal and the plurality of air holes being respectively located on a plurality of primary cells of the photonic crystal;
dividing the photonic crystal into a left region and a right region;
shifting the left region to the left for a first preset distance;
shifting the right region to the left by a second preset distance, or rotating the right region with a preset angle along a point on an interface between the left region and the right region wherein a portion of the right region located at a right side of the interface are preserved.

2. The preparation method of the photonic crystal laser according to claim 1, wherein a range of the first preset distance is:
$$0 \leq d s \leq 0.35 a ,$$
wherein ds is the first preset distance, and a is a lattice constant of the photonic crystal.

3. The preparation method of the photonic crystal laser according to claim 1, wherein an expression of the second preset distance is:
$${Δ}_{i} = \frac{( i - 1 ) a}{n} ,$$
wherein Δᵢ is a second preset distance of a translation of an ith row of the air holes, a is a lattice constant of the photonic crystal, and n is a total number of rows of the air holes.

4. The preparation method of the photonic crystal laser according to claim 1, wherein an expression of the second preset distance is:
$${Δ}_{i} = a [ \frac{i - 1}{n} + \frac{sin ( \frac{2 π ( i - 1 )}{n} )}{3 π} ] ,$$
wherein Δᵢ is a second preset distance of a translation of an ith row of the air holes, a is a lattice constant of the photonic crystal, and n is a total number of rows of the air holes.

5. The preparation method of the photonic crystal laser according to claim 1, in the step of rotating the right region with the preset angle along the point on the interface between the left region and the right region, comprising:
rotating the right region clockwise along the point at a top of the interface to the preset angle ranging from 0° to 30°.

6. The preparation method of the photonic crystal laser according to claim 1, wherein the photonic crystal is formed on the semiconductor wafers with different gain material design including quantum wells, quantum dots or superlattices.

7. The preparation method of the photonic crystal laser according to claim 1, wherein a lattice arrangement of the photonic crystal includes square lattice, triangular lattice, tetragonal lattice, and honeycomb lattice.

8. The preparation method of the photonic crystal laser according to claim 1, wherein a shape of the air holes is circular, triangular, rectangular, or hexagonal.

9. The preparation method of the photonic crystal laser according to claim 8, wherein the shape of the air holes is circular, and a relationship between a diameter of the air holes and a lattice constant is as follows:
$$0.1 \leq \frac{d}{a} \leq 0.95 ,$$
wherein d is the diameter of the air holes and a is the lattice constant of the photonic crystal.

10. A photonic crystal laser, wherein the photonic crystal laser is prepared by the preparation method of the photonic crystal laser according to claim 1.

11. A photonic crystal laser, wherein the photonic crystal laser is prepared by the preparation method of the photonic crystal laser according to claim 2.

12. A photonic crystal laser, wherein the photonic crystal laser is prepared by the preparation method of the photonic crystal laser according to claim 3.

13. A photonic crystal laser, wherein the photonic crystal laser is prepared by the preparation method of the photonic crystal laser according to claim 4.

14. A photonic crystal laser, wherein the photonic crystal laser is prepared by the preparation method of the photonic crystal laser according to claim 5.

15. A photonic crystal laser, wherein the photonic crystal laser is prepared by the preparation method of the photonic crystal laser according to claim 6.

16. A photonic crystal laser, wherein the photonic crystal laser is prepared by the preparation method of the photonic crystal laser according to claim 7.

17. A photonic crystal laser, wherein the photonic crystal laser is prepared by the preparation method of the photonic crystal laser according to claim 8.

18. A photonic crystal laser, wherein the photonic crystal laser is prepared by the preparation method of the photonic crystal laser according to claim 9.
